(19) United States
(12) Patent Application Publication
(10) Pub. No.: US 2015/0228918 A1
(43) Pub. Date: Aug. 13, 2015

(54) SOLAR CELL

(71) Applicants: HITACHI ZOSEN CORPORATION, Osaka (JP); KYOTO UNIVERSITY, Kyoto (JP)

(72) Inventors: Kazushi Hiraoka, Osaka-shi (JP); Kazunari Matsuda, Uji-shi (JP); Yuhei Miyauchi, Uji-shi (JP); Shinichirou Mouri, Uji-shi (JP)

(73) Assignees: KYOTO UNIVERSITY, Sakyo-ku, Kyoto-shi, Kyoto (JP); HITACHI ZOSEN CORPORATION, Suminoe-ku, Osaka-shi, Osaka (JP)

(21) Appl. No.: 14/424,558

(22) PCT Filed: Aug. 27, 2013
(86) PCT No.: PCT/JP2013/072804

§ 371 Date: Feb. 27, 2015

(30) Foreign Application Priority Data
Aug. 30, 2012 (JP) 2012-189338

(51) Int. Cl. H01L 51/42; H01L 51/00

(52) U.S. Cl. CPC H01L 51/4293; H01L 51/0048; H01L 51/442

(57) ABSTRACT

A solar cell includes a translucent member disposed on the incident side of sunlight, an electrode member disposed on the opposite side from the incident side of sunlight and includes a positive electrode and a negative electrode, and an electricity-generating layer that is disposed between the translucent member and the electrode member and is composed of carbon nanotubes, the electricity-generating layer including a p-type first carbon nanotube layer that is disposed near the electrode member and is electrically connected to the positive electrode, and an n-type second carbon nanotube layer that is disposed near the translucent member and is partially electrically connected to the negative electrode 6 via a conductive member.

### FIELD OF THE INVENTION

The present invention relates to a solar cell with carbon nanotubes.

### BACKGROUND OF THE INVENTION

Conventionally, solar cells with carbon nanotubes (CNTs) have been proposed. Such solar cells require electrodes in the incident direction of sunlight. Thus, electrodes provided on the incident side of sunlight are transparent or are shaped like combs that allow entry of sunlight (for example, see Japanese Patent Laid-Open No. 2011-44511).

### SUMMARY OF INVENTION

Unfortunately, the use of transparent electrodes in conventional solar cells with carbon nanotubes leads to a high resistance value and a large power loss and requires expensive electrode materials. In the case of comb-shaped electrodes, sunlight is disadvantageously blocked by the electrodes, leading to low electrical efficiency.

An object of the present invention is to provide a solar cell with carbon nanotubes that can eliminate the need for electrodes on the incident side of sunlight.

In order to attain the object, a first solar cell of the present invention includes a translucent member disposed on the incident side of light, an electrode member disposed on the opposite side from the incident side of light, and an electricity-generating layer that is disposed between the translucent member and the electrode member and is composed of carbon nanotubes (group),

the electrode member including a positive electrode and a negative electrode,

the electricity-generating layer including:

a mixed carbon nanotube layer that is disposed near the translucent member and contains an n-type carbon nanotube and a p-type carbon nanotube in a mixed manner, a p-type carbon nanotube layer disposed between the mixed carbon nanotube layer and the positive electrode, and an n-type carbon nanotube layer disposed between the mixed carbon nanotube layer and the negative electrode.

A second solar cell of the present invention includes a translucent member disposed on the incident side of light, an electrode member disposed on the opposite side from the incident side of light, and an electricity-generating layer that is disposed between the translucent member and the electrode member and is composed of carbon nanotubes (group),

the electrode member including a positive electrode and a negative electrode,

the electricity-generating layer including:

a p-type or n-type first carbon nanotube layer that is disposed near the electrode member and is electrically connected to one of the electrodes, and an n-type or p-type second carbon nanotube layer that is disposed near the translucent member and is partially electrically connected to the other electrode.

A third solar cell of the present invention includes a translucent member disposed on the incident side of light, an electrode member disposed on the opposite side from the incident side of light, and an electricity-generating layer that is disposed between the translucent member and the electrode member and is composed of carbon nanotubes (group),

the electrode member including a positive electrode and a negative electrode,

the electricity-generating layer including:

a p-type or n-type first carbon nanotube layer that is disposed near the electrode member and is electrically connected to one of the electrodes, and an n-type or p-type second carbon nanotube layer that is disposed near the translucent member,

the solar cell further including an insulating layer disposed on the surface of the electrode having the same polarity as the second carbon nanotube layer, and a conductive member that electrically connects the electrode and the second carbon nanotube layer.

A fourth solar cell of the present invention further includes, between the first carbon nanotube layer and the second carbon nanotube layer of the electricity-generating layer in one of the second and third solar cells, one of an i-type third carbon nanotube layer and a third carbon nanotube layer containing the n-type carbon nanotube and the p-type carbon nanotube in a mixed manner.

A fifth solar cell of the present invention includes a translucent member disposed on the incident side of light, an electrode member that is disposed on the opposite side from the incident side of light and includes a positive electrode and a negative electrode, and a carbon nanotube layer disposed between the translucent member and the electrode member,

the carbon nanotube layer serving as a p-type layer,

the positive electrode being made of a metal having substantially the same electronegativity as a carbon nanotube,

the negative electrode being made of a metal having lower electronegativity than the carbon nanotube.

According to a sixth solar cell of the present invention, the metal having substantially the same electronegativity as the carbon nanotube in the fifth solar cell is selected from Au, Cu, Pd, and Pt.

According to a seventh solar cell of the present invention, the metal having lower electronegativity than the carbon nanotube in the fifth solar cell is selected from Cs, Ba, Ca, K, Li, Mg, Na, and Rb.

According to the configurations of the solar cells, the positive electrode and the negative electrode, that is, the electrode member is placed on one surface of the electricity-generating layer. This can eliminate the need for transparent electrodes or comb-shaped electrodes unlike in the conventional configuration, thereby achieving lower manufacturing cost.

Since transparent electrodes are not necessary, a power loss is reduced accordingly. Moreover, this configuration does not block out sunlight unlike comb-shaped electrodes, thereby preventing a reduction in electrical efficiency.

### BRIEF DESCRIPTION OF DRAWINGS

FIG. 1 is a cross-sectional view schematically showing the configuration of a solar cell according to a first embodiment of the present invention.

FIG. 2 is a cross-sectional view schematically showing the configuration of a modification of the solar cell according to the first embodiment of the present invention.

FIG. 3 is a cross-sectional view schematically showing the configuration of a solar cell according to a second embodiment of the present invention.

FIG. 4 is a cross-sectional view schematically showing the configuration of a modification of the solar cell according to the second embodiment of the present invention.

FIG. 5 is a cross-sectional view schematically showing the configuration of a solar cell according to a third embodiment of the present invention.

FIG. 6 is a cross-sectional view schematically showing the configuration of a modification of the solar cell according to the third embodiment of the present invention.

FIG. 7 is a cross-sectional view schematically showing the configuration of a solar cell according to a fourth embodiment of the present invention.

FIG. 8 is a cross-sectional view schematically showing the configuration of a modification of the solar cell according to the fourth embodiment of the present invention.

FIG. 9 is a cross-sectional view schematically showing the configuration of a solar cell according to a fifth embodiment of the present invention.

FIG. 10 is a cross-sectional view schematically showing the configuration of a solar cell according to a sixth embodiment of the present invention.

### DETAILED DESCRIPTION OF THE PREFERRED EMBODIMENTS

Solar cells with carbon nanotubes according to embodiments of the present invention will be described below.

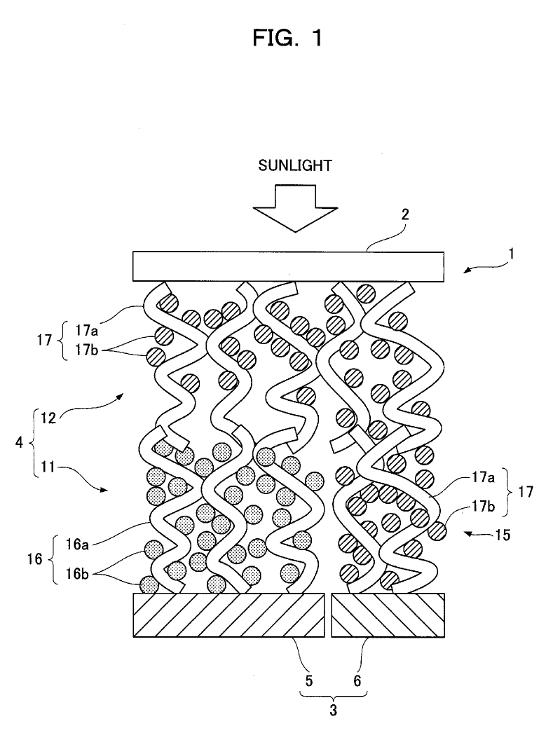

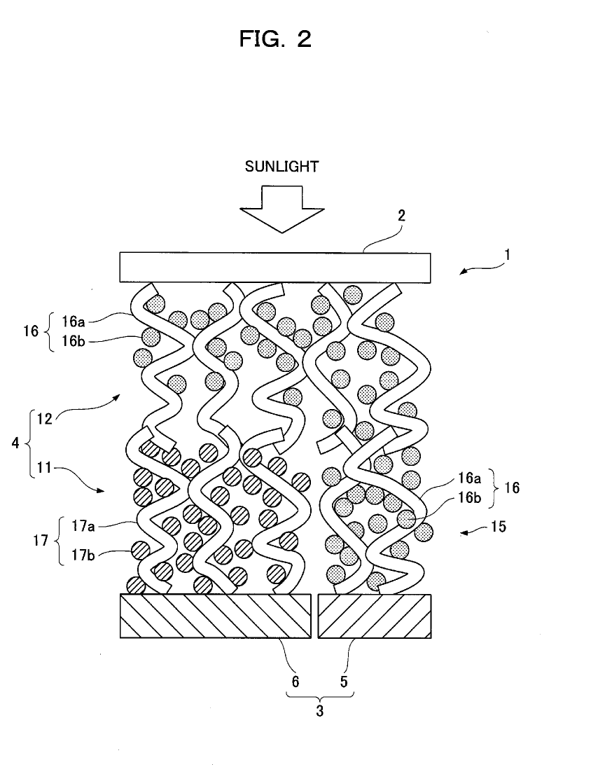

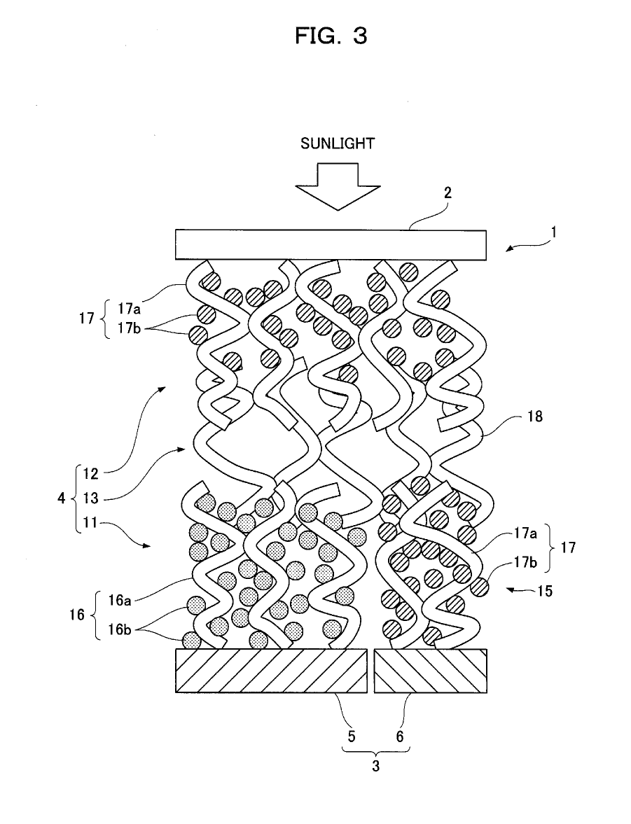

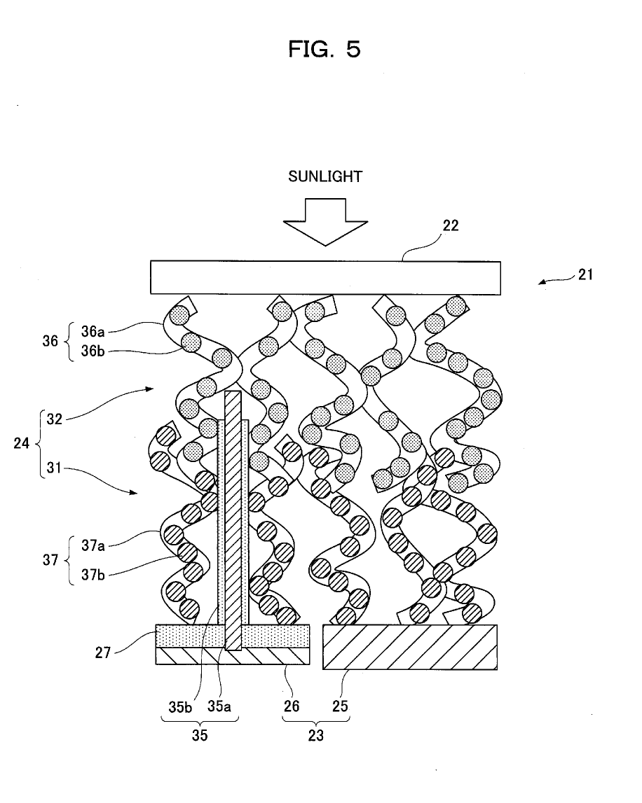

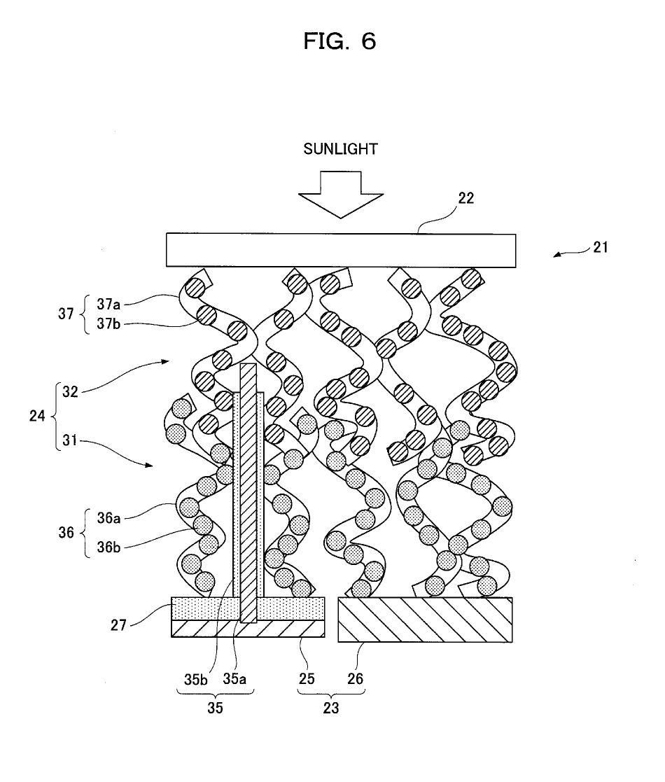

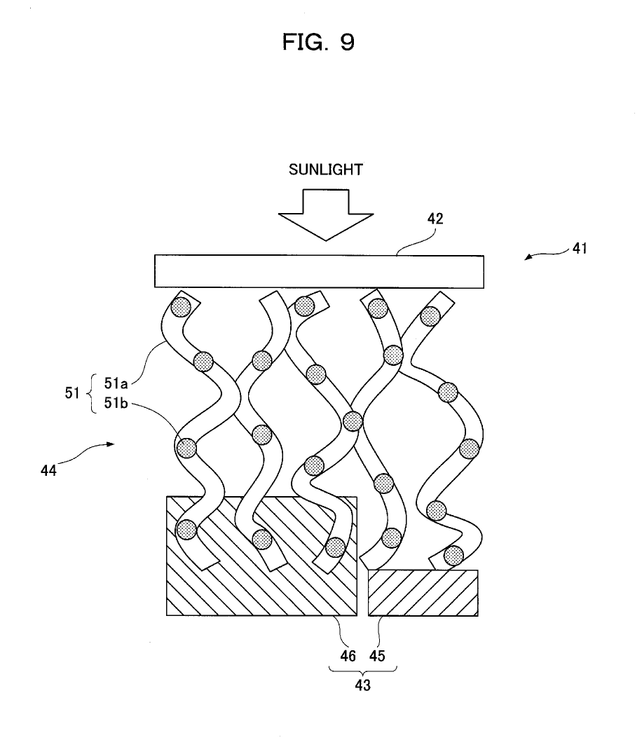

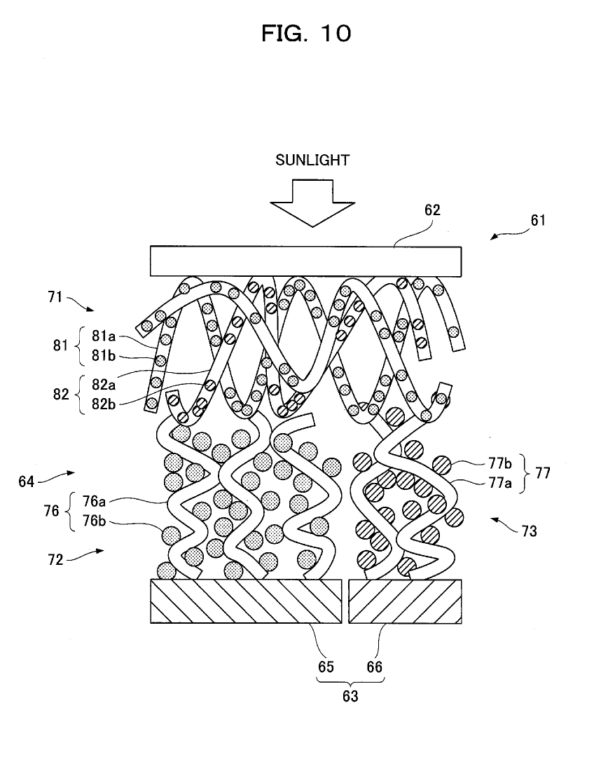

The solar cells are mainly configured such that an electricity-generating layer composed of carbon nanotubes is disposed between an electrode member and a translucent member. The embodiments will be discussed below. In the following explanation, a phrase “carbon nanotubes” implying “group” will be referred to as “carbon nanotube group” when “group” should be emphasized. The main claim numbers in Claims will be indicated below according to the drawing numbers of the solar cells described below in the embodiments. The solar cell of claim 1 corresponds to FIG. 10, the solar cell of claim 2 corresponds to FIGS. 1 and 2, the solar cell of claim 3 corresponds to FIGS. 5 and 6, the solar cell of claim 4 corresponds to FIGS. 3, 4, 7, and 8, and the solar cell of claim 5 corresponds to FIG. 9.

### First Embodiment

A solar cell according to a first embodiment of the present invention will be described below with reference to the accompanying drawings.

As shown in FIG. 1, a solar cell 1 includes a translucent member (a transparent substrate made of materials such as SiO₂ and glass) 2 serving as a window member disposed on the incident side of sunlight, an electrode member 3 disposed on the opposite side (back side) from the incident side of sunlight, and an electricity-generating layer 4 that is disposed between the translucent member 2 and the electrode member 3 and is composed of vertically oriented carbon nanotubes.

The electrode member 3 includes a positive electrode 5 and a negative electrode 6 that are made of one metal selected from, for example, Ag, Au, Cu, In, and Pd.

The electricity-generating layer 4 includes a p-type first carbon nanotube layer 11 that is disposed near the electrode member 3 and is electrically connected to the positive electrode 5, and an n-type second carbon nanotube layer 12 that is disposed near the translucent member 2 and is partially electrically connected to the negative electrode 6 via a conductive member 15. The conductive member 15 is disposed near the negative electrode 6 and includes n-type carbon nanotubes like the second carbon nanotube layer 12.

A p-type carbon nanotube 16 constituting the p-type first carbon nanotube layer 11 includes a p-type dopant 16b that is deposited and supported on the surface of a vertically oriented carbon nanotube 16a.

The p-type dopant is an F4TCNQ (fluorinated tetracyanoquinodimethane) compound, an element (e.g., Cl, F, or O) that has higher electronegativity than the carbon nanotube 16a, or an acid, e.g., HNO₃, H₂SO₄, or HCl. These dopants are particulate matters or liquids supported on the surfaces of the carbon nanotubes.

An n-type carbon nanotube 17 constituting the n-type second carbon nanotube layer 12 includes an n-type dopant 17b that is deposited and supported on the surface of a vertically oriented carbon nanotube 17a.

Moreover, as the conductive member 15, the n-type carbon nanotube 17 is used as in the second carbon nanotube layer 12, specifically, the n-type dopant 17b is deposited and supported on the surface of the vertically oriented carbon nanotube 17a.

The n-type dopant 17b is a metal having lower electronegativity than the carbon nanotube, for example, one metal selected from Ba, Ca, Cs, Fr, K, Li, Mg, Na, Rb, and Sr.

In the manufacture of the solar cell 1, doping is performed on a region corresponding to the positive electrode 5 and the negative electrode 6 on one surface of a laminar carbon nanotube group composed of vertically oriented carbon nanotubes. Specifically, the p-type dopant and the n-type dopant are supported on the surface of the laminar carbon nanotube group with a mask, forming the first carbon nanotube layer 11 and the conductive member 15.

Subsequently, metallic materials are deposited on a surface corresponding to the first carbon nanotube layer 11 and the conductive member 15, forming the positive electrode 5 and the negative electrode 6 as metal electrodes. This forms the electrode member (also called an electrode layer) 3 on the surfaces (corresponding to the backs) of the first carbon nanotube layer 11 and the conductive member 15.

After that, an n-type dopant is then supported over another laminar carbon nanotube group composed of vertically oriented carbon nanotubes in addition to the laminar carbon nanotube group, forming the second carbon nanotube layer 12.

The second carbon nanotube layer 12 is then placed and bonded onto the other surface of the first carbon nanotube layer 11 on the opposite side from the electrode member 3, forming the electricity-generating layer 4.

Subsequently, the translucent member 2 is placed as a window member on the surface of the second carbon nanotube layer 12 and thus the solar cell 1 is obtained as a basic configuration.

In the solar cell 1, electrons having undergone charge separation on a pn junction interface between the p-type first carbon nanotube layer 11 and the n-type second carbon nanotube layer 12 are moved to the negative electrode 6 through the conductive member 15 and then are collected from the negative electrode 6; meanwhile, positive holes are collected from the positive electrode 5 through the p-type first carbon nanotube layer 11.

Moreover, positive holes and electrons generated on a pn junction interface between the p-type first carbon nanotube layer 11 and the n-type conductive member 15 are collected from the positive electrode 5 and the negative electrode 6, respectively.

According to the configuration of the solar cell 1, the positive electrode 5 and the negative electrode 6, that is, the electrode member 3 is placed on one surface (back) of the electricity-generating layer 4. This can eliminate the need for transparent electrodes or comb-shaped electrodes unlike in the conventional configuration, thereby achieving lower manufacturing cost.

Since transparent electrodes are not necessary, a power loss is reduced accordingly. Moreover, this configuration does not block out sunlight unlike comb-shaped electrodes, thereby preventing a reduction in electrical efficiency.

In the explanation, the dopant is supported on the surface of the carbon nanotube during doping. The dopant may be contained in the carbon nanotube (or lattice substitution). The method of containing the dopant may be ion implantation into the carbon nanotube. Alternatively, the dopant may be contained in the carbon nanotube processed to have an opening in a high vacuum before the opening is closed.

In the formation of the electricity-generating layer 4, the carbon nanotube groups in two layers are bonded to each other. For example, the second carbon nanotube layer 12 may be formed as follows: carbon nanotubes doped with a dopant are applied to the surfaces of the positive electrode 5 and the negative electrode 6 so as to form the first carbon nanotube layer 11 and the conductive member 15, and then carbon nanotubes doped with a dopant are applied to the surfaces of the first carbon nanotube layer 11 and the conductive member 15.

The electricity-generating layer 4 according to the first embodiment includes the p-type first carbon nanotube layer 11 near the electrode member 3, the n-type second carbon nanotube layer 12 near the translucent member 2, and the n-type conductive member 15 near the electrode member 3. As shown in FIG. 2, in the electricity-generating layer 4 of the solar cell 1, the first carbon nanotube layer 11 near the electrode member 3 may be n-type, the second carbon nanotube layer 12 near the translucent member 2 may be p-type, and the conductive member 15 near the electrode member 3 may be p-type. As a matter of course, in this case, the conductive member 15 is composed of the p-type carbon nanotube 16 including the p-type dopant 16b that is deposited and supported on the surface of the vertically oriented carbon nanotube 16a.

### Second Embodiment

A solar cell according to a second embodiment of the present invention will be described below in accordance with the accompanying drawings.

In the solar cell according to the first embodiment, the electricity-generating layer includes the first carbon nanotube layer and the second carbon nanotube layer, whereas an electricity-generating layer in the solar cell according to the second embodiment includes a third carbon nanotube layer between a first carbon nanotube layer and a second carbon nanotube layer. The third carbon nanotube layer may contain an i-type carbon nanotube as an intrinsic semiconductor or n-type carbon nanotubes and p-type carbon nanotubes in a mixed (coexistent) manner. In the second embodiment, configurations other than the third carbon nanotube layer are identical to those of the first embodiment. Thus, the same components are indicated by the same reference numerals and the explanation thereof is omitted.

(1) The third carbon nanotube layer containing the i-type carbon nanotube will be first described below.

As shown in FIG. 3, an electricity-generating layer 4 in a solar cell 1 includes an i-type third carbon nanotube layer 13 between a first carbon nanotube layer 11 and a second carbon nanotube layer 12, the i-type third carbon nanotube layer 13 being composed of an i-type carbon nanotube 18 that serves as an intrinsic semiconductor, that is, the i-type carbon nanotube 18 not doped with a dopant.

The configuration of the solar cell 1 will be schematically described below.

The solar cell 1 includes a translucent member 2 disposed on the incident side of sunlight, an electrode member 3 disposed on the opposite side from the incident side of sunlight, and the electricity-generating layer 4 that is disposed between the translucent member 2 and the electrode member 3 and is composed of carbon nanotubes,

the electrode member 3 including a positive electrode 5 and a negative electrode 6,

the electricity-generating layer 4 including:

the p-type first carbon nanotube layer 11 that is disposed near the electrode member 3 and is electrically connected to the positive electrode 5; the n-type second carbon nanotube layer 12 disposed near the translucent member 2; and the i-type third carbon nanotube layer 13 disposed between the first carbon nanotube layer 11 and the second carbon nanotube layer 12,

the solar cell further including a conductive member 15 composed of a p-type carbon nanotube 16 that electrically connects the second carbon nanotube layer 12 and the negative electrode 6 having the same polarity as the second carbon nanotube layer 12.

In this configuration, an i-type portion is provided in addition to the effect of the solar cell according to the first embodiment. This configuration generates a less steep potential gradient with a wider range than in the case of a pn junction (a pn junction has a steep potential gradient in a narrow range, allowing only the use of light absorbed in the narrow range), that is, sunlight can be absorbed over the wide range, thereby improving the conversion efficiency of sunlight energy.

(2) A modification with mixed n-type carbon nanotubes and p-type carbon nanotubes will be described below.

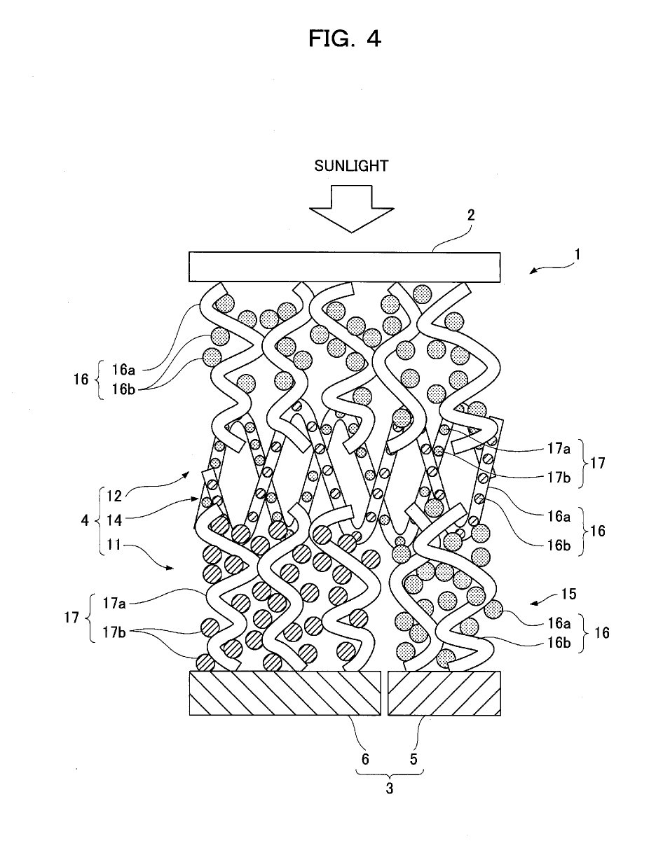

As shown in FIG. 4, the electricity-generating layer 4 in the solar cell 1 includes a third carbon nanotube layer 14 between the first carbon nanotube layer 11 and the second carbon nanotube layer 12, the third carbon nanotube layer 14 containing an n-type carbon nanotube group 17 and the p-type carbon nanotube group 16 in a mixed manner.

The configuration of the solar cell will be schematically described below.

The solar cell 1 includes the translucent member 2 disposed on the incident side of sunlight, the electrode member 3 disposed on the opposite side from the incident side of sunlight, and the electricity-generating layer 4 that is disposed between the translucent member 2 and the electrode member 3 and is composed of carbon nanotubes,

the electrode member 3 including the positive electrode 5 and the negative electrode 6,

the electricity-generating layer 4 including:

the n-type first carbon nanotube layer 11 that is disposed near the electrode member 3 and is electrically connected to the negative electrode 6; the p-type second carbon nanotube layer 12 disposed near the translucent member 2; and the third carbon nanotube layer 14 that is disposed between the first carbon nanotube layer 11 and the second carbon nanotube layer 12 and contains the n-type carbon nanotubes 17 and the p-type carbon nanotubes 16 in a mixed manner,

the solar cell further including the conductive member 15 that electrically connects the second carbon nanotube layer 12 and the positive electrode 5 having the same polarity as the second carbon nanotube layer 12.

In this configuration, a mixed portion of the n-type carbon nanotubes and the p-type carbon nanotubes is provided in addition to the effect of the solar cell according to the first embodiment, achieving higher electrical efficiency.

The polarities of the carbon nanotube groups in the electricity-generating layer 4 described in (1) and (2) may be reversed.

In the manufacturing method of the first embodiment, the electricity-generating layer 4 is fabricated as follows: the first carbon nanotube layer 11 is formed on the surface of the electrode member 3, the third carbon nanotube layer 14 containing the n-type carbon nanotube group 17 and the p-type carbon nanotube group 16 in a mixed manner is stacked thereon, and then the p-type carbon nanotube group 17 is stacked on the surface of the third carbon nanotube layer 14 so as to form the second carbon nanotube layer 12.

### Third Embodiment

A solar cell according to a third embodiment of the present invention will be described below in accordance with the accompanying drawings.

As shown in FIG. 5, a solar cell 21 includes a translucent member (a transparent substrate made of materials such as SiO₂ and glass) 22 serving as a window member disposed on the incident side of sunlight, an electrode member 23 disposed on the opposite side (back side) from the incident side of sunlight, and an electricity-generating layer 24 that is disposed between the translucent member 22 and the electrode member 23 and is composed of carbon nanotubes.

The electrode member 23 includes a positive electrode 25 and a negative electrode 26 that are made of one metal selected from, for example, Ag, Au, Cu, In, and Pd.

The electricity-generating layer 24 includes an n-type first carbon nanotube layer 31 disposed near the electrode member 23 and a p-type second carbon nanotube layer 32 disposed near the translucent member 22. As a matter of course, the n-type first carbon nanotube layer 31 is electrically connected to the negative electrode 26 while the p-type second carbon nanotube layer 32 is electrically connected to the positive electrode 25.

Specifically, the negative electrode 26 is directly brought into contact with the first carbon nanotube layer 31 while the positive electrode 25 and the second carbon nanotube layer 32 are electrically connected to each other via a conductive member 35 that is inserted with an insulated surface into the first carbon nanotube layer 31.

The conductive member 35 includes a plurality of conductive metallic pins (may be called electrode pins) 35a that are raised at predetermined intervals on the surface of the positive electrode 25 so as to electrically connect the electrode 25 and the second carbon nanotube layer 32, and an insulating film 35b formed on the outer surface of the metallic pin 35a corresponding to the first carbon nanotube layer 31. As a matter of course, the insulating film 35b formed on the metallic pin 35a is extended longer than the thickness of the first carbon nanotube layer 31 and thus the end of the metallic pin 35a is protruded from the insulating film 35b.

The surface of the positive electrode 25 has an insulating layer 27 that prevents electrical connection between the positive electrode 25 and the first carbon nanotube layer 31.

With this configuration, the pn junction (junction region) of the carbon nanotube layers 31 and 32 is formed over the electrode member 23. The pn junction may have a bulk hetero structure where a p-type carbon nanotube 36 and an n-type carbon nanotube 37 overlap each other.

The n-type carbon nanotube 37 constituting the n-type first carbon nanotube layer 31 includes a vertically oriented carbon nanotube 37a containing an n-type dopant 37b.

The n-type dopant 37b is a metal having lower electronegativity than the carbon nanotube, for example, one metal selected from Ba, Ca, Cs, Fr, K, Li, Mg, Na, Rb, and Sr.

The p-type carbon nanotube 36 constituting the p-type second carbon nanotube layer 32 includes a vertically oriented carbon nanotube 36a containing a p-type dopant 36b.

The p-type dopant is an F4TCNQ (fluorinated tetracyanoquinodimethane) compound, an element (e.g., Cl, F, or O) that has higher electronegativity than the carbon nanotube, or an acid, e.g., HNO₃, H₂SO₄, or HCl.

The dopant may be contained in the carbon nanotube by ion implantation into the carbon nanotube. Alternatively, the dopant may be contained in the carbon nanotube processed to have an opening in a high vacuum before the opening is closed.

In the manufacture of the solar cell 21, the n-type carbon nanotube group 37 and the p-type carbon nanotube group 36 are obtained beforehand, the n-type carbon nanotube group 37 including the vertically oriented carbon nanotube 37a containing the n-type dopant 37b, the p-type carbon nanotube group 36 including the vertically oriented carbon nanotube 36a containing the p-type dopant 36b.

Furthermore, the positive electrode 25 and the negative electrode 26 are prepared. At this point, the surface of the prepared positive electrode 25 has the multiple metallic pins 35a. The insulating film 35b is formed on the outer surface of the metallic pin 35a whose end is protruded (exposed) from the insulating film 35b.

Subsequently, the n-type carbon nanotube 37 is applied to the surface of the electrode member 23 including the positive electrode 25 and the negative electrode 26 that are placed side by side, forming the n-type first carbon nanotube layer 31. At this point, the end of the metallic pin 35a is protruded upward from the first carbon nanotube layer 31.

The p-type carbon nanotube 36 is stacked on the surface of the first carbon nanotube layer 31, forming the p-type second carbon nanotube layer 32.

Thus, in this state, the second carbon nanotube layer 32 and the positive electrode 25 are electrically connected to each other via the conductive member 35.

Finally, the translucent member 22 is placed as a window member and thus the solar cell 21 is obtained as a basic configuration.

In the solar cell 21, electrons having undergone charge separation on a pn junction interface between the n-type first carbon nanotube layer 31 and the p-type second carbon nanotube layer 32 are collected from the negative electrode 26 through the first carbon nanotube layer 31; meanwhile, positive holes are collected from the positive electrode 25 through the conductive member 35.

According to the configuration of the solar cell 21, the positive electrode 25 and the negative electrode 26, that is, the electrode member 23 is placed on one surface (back) of the electricity-generating layer 24 as in the first embodiment. This can eliminate the need for transparent electrodes or comb-shaped electrodes unlike in the conventional configuration, thereby achieving lower manufacturing cost.

Since transparent electrodes are not necessary, a power loss is reduced accordingly. Moreover, this configuration does not block out sunlight unlike comb-shaped electrodes, thereby preventing a reduction in electrical efficiency.

Moreover, the first carbon nanotube layer 31 and the second carbon nanotube layer 32 are opposed to each other over the surfaces of the layers. This configuration can widen the pn junction so as to improve the electrical efficiency.

In the explanation, the dopant is contained in the carbon nanotube during doping. The dopant may be deposited and supported on the surface of the carbon nanotube.

The electricity-generating layer 24 according to the third embodiment includes the n-type first carbon nanotube layer 31 near the electrode member 23 and the p-type second carbon nanotube layer 32 near the translucent member 22. As shown in FIG. 6, in the electricity-generating layer 24 of the solar cell 21, the first carbon nanotube layer 31 near the electrode member 23 may be p-type and the second carbon nanotube layer 32 near the translucent member 22 may be n-type.

### Fourth Embodiment

A solar cell according to a fourth embodiment of the present invention will be described below in accordance with the accompanying drawings.

In the solar cell according to the third embodiment, the electricity-generating layer includes the first carbon nanotube layer and the second carbon nanotube layer, whereas an electricity-generating layer in the solar cell according to the fourth embodiment includes a third carbon nanotube layer between a first carbon nanotube layer and a second carbon nanotube layer. The third carbon nanotube layer may contain an i-type carbon nanotube as an intrinsic semiconductor or n-type carbon nanotubes and p-type carbon nanotubes in a mixed (coexistent) manner. In the fourth embodiment, configurations other than the third carbon nanotube layer are identical to those of the third embodiment. Thus, the same components are indicated by the same reference numerals and the explanation thereof is omitted.

(1) The third carbon nanotube layer containing the i-type carbon nanotube will be first described below.

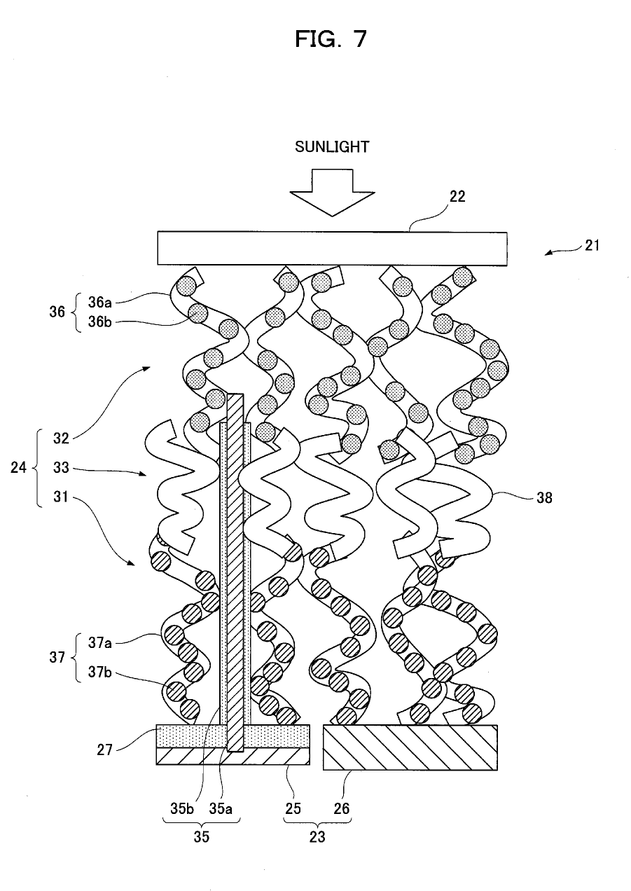

As shown in FIG. 7, an electricity-generating layer 24 in a solar cell 21 includes an i-type third carbon nanotube layer 33 between a first carbon nanotube layer 31 and a second carbon nanotube layer 32, the i-type third carbon nanotube layer 33 being composed of an i-type carbon nanotube 38 that serves as an intrinsic semiconductor, that is, the i-type carbon nanotube 38 not doped with a dopant. Naturally, a conductive member 35 is inserted into the third carbon nanotube layer 33.

The configuration of the solar cell 21 will be schematically described below.

The solar cell 21 includes a translucent member 22 disposed on the incident side of sunlight, an electrode member 23 disposed on the opposite side from the incident side of sunlight, and the electricity-generating layer 24 that is disposed between the translucent member 22 and the electrode member 23 and is composed of carbon nanotubes,

the electrode member 23 including a positive electrode 25 and a negative electrode 26,

the electricity-generating layer 24 including:

the n-type first carbon nanotube layer 31 that is disposed near the electrode member 23 and is electrically connected to the negative electrode 26; the p-type second carbon nanotube layer 32 disposed near the translucent member 22; and the i-type third carbon nanotube layer 33 disposed between the first carbon nanotube layer 31 and the second carbon nanotube layer 32,

the solar cell further including an insulating layer 27 disposed on the surface of the positive electrode 25 having the same polarity as the second carbon nanotube layer 32, and the conductive member 35 that electrically connects the positive electrode 25 and the second carbon nanotube layer 32.

In this configuration, an i-type portion is provided in addition to the effect of the solar cell according to the third embodiment. This configuration generates a less steep potential gradient with a wider range than in the case of a pn junction (a pn junction has a steep potential gradient in a narrow range, allowing only the use of light absorbed in the narrow range), that is, sunlight can be absorbed over the wide range, thereby improving the conversion efficiency of sunlight energy.

(2) A modification with mixed n-type carbon nanotubes and p-type carbon nanotubes will be described below.

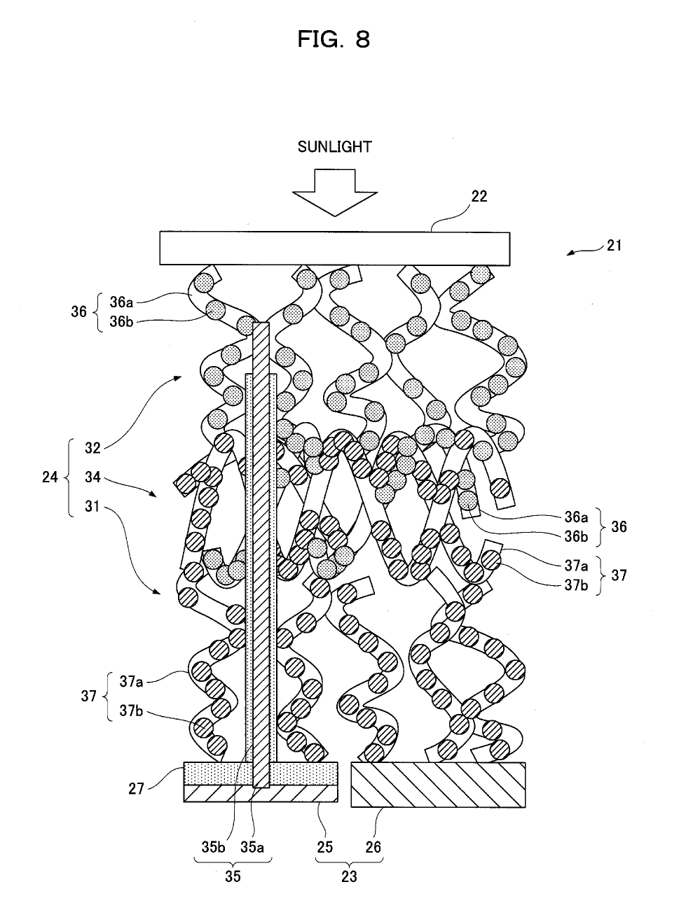

As shown in FIG. 8, the electricity-generating layer 24 in the solar cell 21 includes a third carbon nanotube layer 34 between the first carbon nanotube layer 31 and the second carbon nanotube layer 32, the third carbon nanotube layer 34 containing an n-type carbon nanotube group 37 and a p-type carbon nanotube group 36 in a mixed manner. As a matter of course, the conductive member 35 is inserted into the third carbon nanotube layer 34.

The configuration of the solar cell will be schematically described below.

The solar cell 21 includes the translucent member 22 disposed on the incident side of sunlight, the electrode member 23 disposed on the opposite side from the incident side of sunlight, and the electricity-generating layer 24 that is disposed between the translucent member 22 and the electrode member 23 and is composed of carbon nanotubes,

the electrode member 23 including the positive electrode 25 and the negative electrode 26,

the electricity-generating layer 24 including:

the n-type first carbon nanotube layer 31 that is disposed near the electrode member 23 and is electrically connected to the negative electrode 26; the p-type second carbon nanotube layer 32 disposed near the translucent member 22; and the third carbon nanotube layer 34 that is disposed between the first carbon nanotube layer 31 and the second carbon nanotube layer 32 and contains the n-type carbon nanotubes 37 and the p-type carbon nanotubes 36 in a mixed manner,

the solar cell further including the insulating layer 27 disposed on the surface of the positive electrode 25 having the same polarity as the second carbon nanotube layer 32, and the conductive member 35 that electrically connects the positive electrode 25 and the second carbon nanotube layer 32.

In this configuration, a mixed portion of the n-type carbon nanotubes and the p-type carbon nanotubes is provided in addition to the effect of the solar cell according to the third embodiment, achieving higher electrical efficiency.

In the electricity-generating layer 24 described in (1) and (2), the p-type carbon nanotube layer 32 is disposed near the translucent member 22 while the n-type carbon nanotube layer 31 is disposed near the electrode member 23. The arrangement may be reversed, specifically, the n-type carbon nanotube layer may be disposed near the translucent member 22 while the p-type carbon nanotube layer may be disposed near the electrode member 23.

In the manufacturing method of the third embodiment, the electricity-generating layer 24 is fabricated as follows: the first carbon nanotube layer 31 is formed on the surface of the electrode member 23, the third carbon nanotube layer 33 containing an i-type carbon nanotube group 38 or the third carbon nanotube layer 34 containing the n-type carbon nanotube group 37 and the p-type carbon nanotube group 36 in a mixed manner is stacked on the first carbon nanotube layer 31, and then the p-type carbon nanotube group 36 is stacked on the surface of the third carbon nanotube layer 34 so as to form the p-type second carbon nanotube layer 32.

### Fifth Embodiment

A solar cell according to a fifth embodiment of the present invention will be described below in accordance with the accompanying drawings.

As shown in FIG. 9, a solar cell 41 includes a translucent member (a transparent substrate made of materials such as SiO₂ and glass) 42 serving as a window member disposed on the incident side of sunlight, an electrode member 43 disposed on the opposite side (back side) from the incident side of sunlight, and a carbon nanotube layer 44 that is disposed between the translucent member 42 and the electrode member 43 and is composed of carbon nanotubes.

The carbon nanotube layer 44 is p-type. A p-type carbon nanotube 51 constituting the carbon nanotube layer 44 includes a vertically oriented carbon nanotube 51a containing a p-type dopant 51b.

The p-type dopant is an F4TCNQ (fluorinated tetracyanoquinodimethane) compound, an element (e.g., Cl, F, or O) that has higher electronegativity than the carbon nanotube 51a, or an acid, e.g., HNO₃, H₂SO₄, or HCl. The dopant may be contained in the carbon nanotube by ion implantation into the carbon nanotube. Alternatively, the dopant may be contained in the carbon nanotube processed to have an opening in a high vacuum before the opening is closed.

The electrode member 43 includes a positive electrode 45 and a negative electrode 46.

The positive electrode 45 is made of a metal having substantially the same electronegativity as the carbon nanotube 51a, for example, one of Au, Cu, Pd, and Pt.

The negative electrode 46 is made of a metal having lower electronegativity than the carbon nanotube 51a, for example, one of Cs, Ba, Ca, K, Li, Mg, Na, and Rb. Additionally, the negative electrode 46 contains a part of the carbon nanotube 51a that forms the carbon nanotube layer 44.

Since the negative electrode 46 is made of a metal having lower electronegativity than the carbon nanotube 51a, the carbon nanotube 51a of n-type is contained in the negative electrode 46 of the carbon nanotube layer 44. Thus, this portion forms a pn junction on the carbon nanotube 51a.

In the solar cell 41, electrons having undergone charge separation on a pn junction interface that is a boundary between the p-type carbon nanotube layer 44 and the carbon nanotube 51a contained in the negative electrode 46 are collected from the negative electrode 46; meanwhile, positive holes are collected from the positive electrode 45 through the carbon nanotube layer 44.

The manufacturing method of the solar cell 41 will be briefly described below.

In the manufacture of the solar cell 41, the laminar p-type carbon nanotube 51 is obtained beforehand. The p-type carbon nanotube 51 includes the vertically oriented carbon nanotube 51a containing the p-type dopant 51b.

Furthermore, the positive electrode 45 is formed on a part of the surface of the laminar p-type carbon nanotube group 51 by evaporation and so on, and then the negative electrode 46 is formed on the other part by evaporation and so on. The negative electrode 46 is formed so as to contain a part of the p-type carbon nanotube group 51. In this way, the carbon nanotube layer 44 is formed on the surface of the electrode member 43 that includes the positive electrode 45 and the negative electrode 46.

Subsequently, the translucent member 42 is placed as a window member on the opposite surface of the carbon nanotube layer 44 from the electrode member 43 and thus the solar cell 41 is obtained as a basic configuration.

According to the configuration of the solar cell 41, the positive electrode 45 and the negative electrode 46, that is, the electrode member 43 is placed on one surface (back) of the carbon nanotube layer 44 as in the first embodiment. This can eliminate the need for transparent electrodes or comb-shaped electrodes unlike in the conventional configuration, thereby achieving lower manufacturing cost.

Since transparent electrodes are not necessary, a power loss is reduced accordingly. Moreover, this configuration does not block out sunlight unlike comb-shaped electrodes, thereby preventing a reduction in electrical efficiency.

### Sixth Embodiment

A solar cell according to a sixth embodiment of the present invention will be described below in accordance with the accompanying drawings.

As shown in FIG. 10, a solar cell 61 includes a translucent member (a transparent substrate made of materials such as SiO₂ and glass) 62 serving as a window member disposed on the incident side of sunlight, an electrode member 63 disposed on the opposite side (back side) from the incident side of sunlight, and an electricity-generating layer 64 that is disposed between the translucent member 62 and the electrode member 63 and is composed of vertically oriented carbon nanotubes.

The electrode member 63 includes a positive electrode 65 and a negative electrode 66 that are made of one metal selected from, for example, Ag, Au, Cu, In, and Pd.

The electricity-generating layer 64 includes a mixed carbon nanotube layer 71 that is disposed near the translucent member 62 and contains a p-type carbon nanotube 81 and an n-type carbon nanotube 82 in a mixed manner, a p-type carbon nanotube layer 72 that is disposed between the mixed carbon nanotube layer 71 and the positive electrode 65 of the electrode member 63 and contains a p-type carbon nanotube 76, and an n-type carbon nanotube layer 73 that is disposed between the mixed carbon nanotube layer 71 and the negative electrode 66 of the electrode member 63 and contains the n-type carbon nanotube 82.

The p-type carbon nanotube 81 constituting the mixed carbon nanotube layer 71 includes a vertically oriented carbon nanotube 81a containing a p-type dopant 81b.

The p-type dopant is an F4TCNQ (fluorinated tetracyanoquinodimethane) compound, an element (e.g., Cl, F, or O) that has higher electronegativity than the carbon nanotube 81a, or an acid, e.g., HNO₃, H₂SO₄, or HCl.

The n-type carbon nanotube 82 includes a vertically oriented carbon nanotube 82a containing an n-type dopant 82b.

The n-type dopant 82b is a metal having lower electronegativity than the carbon nanotube, for example, one metal selected from Ba, Ca, Cs, Fr, K, Li, Mg, Na, Rb, and Sr.

The dopant may be contained in the carbon nanotube by ion implantation into the carbon nanotube. Alternatively, the dopant may be contained in the carbon nanotube processed to have an opening in a high vacuum before the opening is closed.

The p-type carbon nanotube 76 constituting the p-type carbon nanotube layer 72 includes a p-type dopant 76b that is deposited and supported on the surface of a vertically oriented carbon nanotube 76a.

The p-type dopant 76b is an F4TCNQ (fluorinated tetracyanoquinodimethane) compound, an element (e.g., Cl, F, or O) that has higher electronegativity than the carbon nanotube 76a, or an acid, e.g., HNO₃, H₂SO₄, or HCl. These dopants are particulates or liquids supported on the surface of the carbon nanotube.

Moreover, an n-type carbon nanotube 77 constituting the n-type carbon nanotube layer 73 includes an n-type dopant 77b that is deposited and supported on the surface of a vertically oriented carbon nanotube 77a.

The n-type dopant 77b is a metal having lower electronegativity than the carbon nanotube, for example, one metal selected from Ba, Ca, Cs, Fr, K, Li, Mg, Na, Rb, and Sr.

In the manufacture of the solar cell 61, doping is performed on a region corresponding to the positive electrode 65 and the negative electrode 66 on one surface of the laminar carbon nanotube group composed of vertically oriented carbon nanotubes. Specifically, the p-type dopant and the n-type dopant are supported on the surface of the laminar carbon nanotube group with a mask, forming the p-type first carbon nanotube layer 72 and the n-type carbon nanotube layer 73.

Subsequently, metallic materials are deposited on a surface corresponding to the p-type carbon nanotube layer 72 and the n-type carbon nanotube layer 73, forming the positive electrode 65 and the negative electrode 66 as metal electrodes. Thus, the electrode member (also called an electrode layer) 63 is formed.

After that, the p-type carbon nanotube 81 and the n-type carbon nanotube 82 are applied in a mixed state to the opposite surfaces of the carbon nanotube layers 72 and 73 from the electrode member 63 so as to form the mixed carbon nanotube layer 71, forming the electricity-generating layer 64.

Subsequently, the translucent member 62 is placed as a window member on the surface of the mixed carbon nanotube layer 71 and thus the solar cell 61 is obtained as a basic configuration.

In the solar cell 61, electrons having undergone charge separation on a pn junction interface between the p-type carbon nanotube 81 and the n-type carbon nanotube 82 of the mixed carbon nanotube layer 71 are moved to the negative electrode 66 through the n-type carbon nanotube layer 73 and then are collected from the negative electrode 66; meanwhile, positive holes are collected from the positive electrode 65 through the p-type carbon nanotube layer 72.

According to the configuration of the solar cell 61, the positive electrode 65 and the negative electrode 66, that is, the electrode member 63 is placed on one surface (back) of the electricity-generating layer 64. This can eliminate the need for transparent electrodes or comb-shaped electrodes unlike in the conventional configuration, thereby achieving lower manufacturing cost.

Since transparent electrodes are not necessary, a power loss is reduced accordingly. Moreover, this configuration does not block out sunlight unlike comb-shaped electrodes, thereby preventing a reduction in electrical efficiency.

In the explanation, the dopant is supported on the surface of the carbon nanotube during the formation of the p-type carbon nanotube layer 72 and the n-type carbon nanotube layer 73. The dopant may be contained in the carbon nanotube (or lattice substitution) as in the case of the mixed carbon nanotube layer 71. Also in the mixed carbon nanotube layer 71, the dopant may be supported on the surface of the carbon nanotube.

1. A solar cell comprising a translucent member disposed on an incident side of light, an electrode member disposed on an opposite side from the incident side of light, and an electricity-generating layer that is disposed between the translucent member and the electrode member and is composed of carbon nanotubes,
the electrode member including a positive electrode and a negative electrode,
the electricity-generating layer including:
a mixed carbon nanotube layer that is disposed near the translucent member and contains an n-type carbon nanotube and a p-type carbon nanotube in a mixed manner, a p-type carbon nanotube layer disposed between the mixed carbon nanotube layer and the positive electrode, and an n-type carbon nanotube layer disposed between the mixed carbon nanotube layer and the negative electrode.

2. A solar cell comprising a translucent member disposed on an incident side of light, an electrode member disposed on an opposite side from the incident side of light, and an electricity-generating layer that is disposed between the translucent member and the electrode member and is composed of carbon nanotubes,
the electrode member including a positive electrode and a negative electrode,
the electricity-generating layer including:
a p-type or n-type first carbon nanotube layer that is disposed near the electrode member and is electrically connected to one of the electrodes, and an n-type or p-type second carbon nanotube layer that is disposed near the translucent member and is partially electrically connected to the other electrode.

3. A solar cell comprising a translucent member disposed on an incident side of light, an electrode member disposed on an opposite side from the incident side of light, and an electricity-generating layer that is disposed between the translucent member and the electrode member and is composed of carbon nanotubes,
the electrode member including a positive electrode and a negative electrode,
the electricity-generating layer including:
a p-type or n-type first carbon nanotube layer that is disposed near the electrode member and is electrically connected to one of the electrodes, and an n-type or p-type second carbon nanotube layer that is disposed near the translucent member,
the solar cell further including an insulating layer disposed on a surface of the electrode having the same polarity as the second carbon nanotube layer, and a conductive member that electrically connects the electrode and the second carbon nanotube layer.

4. The solar cell according claim 2, further comprising, between the first carbon nanotube layer and the second carbon nanotube layer, one of an i-type third carbon nanotube layer and a third carbon nanotube layer containing the n-type carbon nanotube and the p-type carbon nanotube in a mixed manner.

5. A solar cell comprising a translucent member disposed on an incident side of light, an electrode member that is disposed on an opposite side from the incident side of light and includes a positive electrode and a negative electrode, and a carbon nanotube layer disposed between the translucent member and the electrode member,
the carbon nanotube layer serving as a p-type layer,
the positive electrode being made of a metal having substantially the same electronegativity as a carbon nanotube,
the negative electrode being made of a metal having lower electronegativity than the carbon nanotube.

6. The solar cell according to claim 5, wherein the metal having substantially the same electronegativity as the carbon nanotube is selected from Au, Cu, Pd, and Pt.

7. The solar cell according to claim 5, wherein the metal having lower electronegativity than the carbon nanotube is selected from Cs, Ba, Ca, K, Li, Mg, Na, and Rb.

8. The solar cell according claim 3, further comprising, between the first carbon nanotube layer and the second carbon nanotube layer, one of an i-type third carbon nanotube layer and a third carbon nanotube layer containing the n-type carbon nanotube and the p-type carbon nanotube in a mixed manner.
